(19) United States
(12) Patent Application Publication
(10) Pub. No.: US 2007/0278515 A1
(43) Pub. Date: Dec. 6, 2007

(54) Silicon controlled rectifier protection circuit

(76) Inventor: Roger S. Hurst, Austin, TX (US)

Correspondence Address: TROP PRUNER & HU, PC, 1616 S. VOSS ROAD, SUITE 750, HOUSTON, TX, 77057-2631, US

(21) Appl. No.: 11/444,021

(22) Filed: May 31, 2006

(51) Int. Cl. H01L 29/74

(52) U.S. Cl. 257/173

(57) ABSTRACT

In one embodiment, the present invention includes an apparatus having a protection circuit to provide protection from transient surges. The protection circuit may include a silicon controlled rectifier (SCR) that is formed on a substrate via a planar process, along with one or more circuits to be protected by the protection circuit.

### FIELD OF THE INVENTION

The present invention relates to an integrated circuit and more particularly to an integrated circuit including protection circuitry.

### BACKGROUND

Various circuits such as telecommunication line card circuits are subjected to very harsh environments, as their terminals (i.e., tip and ring lines) extend from a central office to a subscriber location over telephone poles that are subject to lightning strikes and power crosses. This presents a need to protect the line card from damage due to lightning and power crosses. Protection of the line card is normally done in two stages. The first stage is a primary protection stage which drops the voltage down to a more manageable level (e.g., in the 1000V range). The second stage is a secondary protection stage which limits the voltage seen by the line card even further by shunting current to ground.

The particular circuit being protected on a line card typically includes a circuit called a subscriber line interface circuit (SLIC) that acts as an interface between central office and subscriber equipment. The SLIC is typically a high voltage (e.g., 48V to 150V) integrated circuit that is used to power the phone line, transmit and receive voice signals to and from the phone and to provide line supervision (i.e., senses when the phone goes on and off-hook, etc.).

The secondary protection stage of the protection network is normally made up of two fuse resistors on the order of 50 ohms, several diodes and thyristors or silicon controlled rectifiers (SCRs). This network is used to clamp an incoming voltage to a level that the SLIC can withstand without being damaged while shunting currents of up to 50 Amperes (Amps) to ground. The SCR shunts current and clamps the voltage on negative-going voltage transients and the diode shunts current and clamps the voltage on positive-going voltage transients. A transient surge current applied to the input of the protection circuit can have peak currents in the range of 50 A for a 10 (uS) surge and 20 A for a 1000 uS surge.

The SCR must be able to sink these current levels while limiting the voltage rise. The voltage drop across the SCR at 50 A is typically limited to less than 10V (and thus the SCR must exhibit less than 0.2 ohms impedance at peak currents). Further, the SCR cannot turn on during normal operation of the SLIC. This means the breakdown voltage of the device must be greater than 48V (for non-ringing operation) and from 75V to 150V to support ringing voltages. The SCR must also turn off when the current through the device drops below 100 mA.

Silicon devices that need to have high breakdowns require unique processes that have lightly doped silicon regions to achieve these levels of breakdown. The need for lightly doped regions causes the devices to get large. The lightly doped regions cause the resistivity to be high as well, making it difficult to achieve low on resistances without growing the device area to sizes that are not economical. For this reason, implementation of SCRs for use in protection circuits has typically been done with discrete processes. In these processes, the device action is from a front side of a wafer to a backside of the wafer. These types of structures (i.e., vertical discrete devices) cannot be integrated into traditional bipolar or bipolar complementary metal oxide semiconductor (biCMOS) planar processes and act as protection devices. An obstacle preventing integration of these devices is that parasitic diodes and transistors turn on prematurely on negative-going transients that cause forward biasing of the substrate in junction-isolated processes. This prevents proper operation of the SCR and prevents proper protection when used in a protection circuit. A need exists for improved protection circuits and to provide lower cost solutions for such circuits.

### SUMMARY OF THE INVENTION

In one aspect, the present invention includes an apparatus having a protection circuit to provide protection from transient surges. The protection circuit may include a silicon controlled rectifier (SCR) formed on a substrate via a planar process. Further, this SCR may be formed on the same substrate as a circuit to be protected by the protection circuit. As one example, the circuit to be protected can be a subscriber line interface circuit (SLIC). The SCR can be formed of multiple bipolar transistors having common collector-base diffusions. These transistors may have a large breakdown voltage, e.g., in part due to lightly doped p-well and n-well regions and an isolation region formed between these p-well and n-well regions.

Another aspect of the present invention resides in a method for forming a p-well region on a substrate via implantation of a p-type dopant along a p-well region while blocking a portion of the p-well region, and forming an n-well region on the substrate adjacent the p-well region. In this way, a vertical junction between the n-well region and the p-well region may be formed that acts as a vertical junction of a lateral SCR. In one implementation, the method may be performed using a silicon on insulator (SOI) process in which an insulation layer is formed between a handle wafer region of the substrate and the n-well and p-well regions. The method may further include forming a circuit on the substrate that is to be protected from high voltage surges by the SCR.

Still further aspects of the present invention are directed to a system that includes a circuit formed on a substrate, a SCR coupled to the circuit having a vertical junction between a first common collector terminal of a first transistor and a second common collector terminal of a second transistor, and a line card. The SCR may be formed in the same integrated circuit (IC) as the circuit, which may be a SLIC or other such device.

### BRIEF DESCRIPTION OF THE DRAWINGS

FIG. 1 is a schematic diagram of an SCR in accordance with an embodiment of the present invention.

FIG. 2 is a cross section of an SCR in accordance with one embodiment of the present invention.

FIG. 3 is a cross section of an SCR in accordance with another embodiment of the present invention.

FIG. 4 is a layout of a single SCR cell in accordance with an embodiment of the present invention.

FIG. 5 is a layout of a circuit in accordance with another embodiment of the present invention.

FIG. 6 is a block diagram of a system in accordance with an embodiment of the present invention.

### DETAILED DESCRIPTION

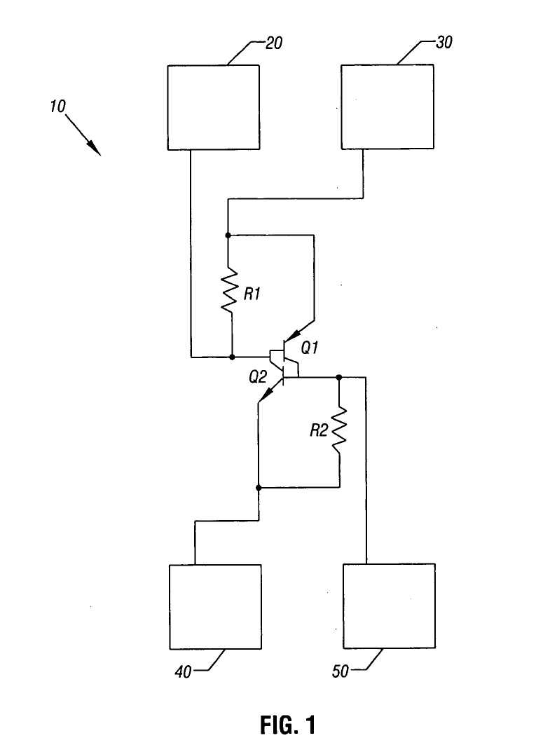

Referring now to FIG. 1, shown is a schematic diagram of a SCR in accordance with an embodiment of the present invention. As shown in FIG. 1, SCR 10 is formed of two transistors, namely a first transistor Q1 and a second transistor Q2. As shown in FIG. 1, first transistor Q1 may be a bipolar transistor, more specifically a PNP-type bipolar transistor, while second transistor Q2 may be an NPN-type bipolar transistor. As shown, the emitter of transistor Q1 is coupled to a bond pad 30, which may be an input/output (I/O) pin. Furthermore, the emitter is coupled to one end of a bypass resistor R1, for example, a 100 ohm resistor in one embodiment. The base of transistor Q1 is coupled to the other end of resistor R1 and another bond pad 20.

Still referring to FIG. 1, the collector of transistor Q1 is connected via a common or shared diffusion to the base of transistor Q2 and is further coupled to a second bypass resistor R2, which may also be a 100 ohm resistor, in one embodiment. Furthermore, the collector of transistor Q1 (and the base of transistor Q2) are further coupled to a bond pad 50. Note further that the emitter of transistor Q2 is coupled to the other end of resistor R2 and a bond pad 40 and the collector of Q2 is connected via a common diffusion to the base of transistor Q1. The junction between the collectors may be a vertical junction formed by lightly doped P and N regions.

Using SCR 10 of FIG. 1, a diode of a clamping network can be coupled with its cathode coupled to the emitter of transistor Q1 and its anode coupled to the emitter of transistor Q2. With such a configuration, SCR 10 may be used as a protection device, e.g., to protect an underlying circuit from electrical surges such as caused by a lightning strike or other conditions on a line coupled to the circuit.

In accordance with various embodiments, SCR 10 of FIG. 1 may be formed on a substrate using a planar process. Furthermore, the SCR may be formed on a substrate that further includes the underlying circuit to be protected by the SCR. In this way, reduced component count and area is realized, reducing costs. In various implementations, an integrated SCR may be formed with the underlying circuit on a substrate using a silicon on insulator (SOI) process, although the scope of the present invention is not limited in this regard.

By using an SOI process, parasitic interactions preventing proper operation of an SCR during protection events are eliminated. While the scope of the present invention is not limited in this regard, breakdown voltages exceeding 100V may be realized, and may range from approximately 48V to 150V, in implementations for use with a SLIC. Because no parasitic devices will turn on during transient stages, proper operation of the SCR can occur. This allows the SCR to be integrated into the same substrate as the underlying circuit, e.g., a SLIC. Since the SLIC process uses transistors having high breakdown voltages as well, breakdown requirements of the SCR can be met. Accordingly, these high breakdown voltages correlate with the breakdown voltage of transistors of the underlying circuit. Using a SOI process, junction isolation is eliminated and an oxide layer provides the isolation of the device. In one embodiment, an SCR may be formed using a high voltage SOI combined bipolar CMOS, double diffusion metal oxide semiconductor (BCDMOS) process to meet the required lightning protection requirements, although other processes are possible.

In various implementations, an inherent breakdown voltage of a given SOI process can be increased by performing certain diffusions in doping a substrate. For example, as will be discussed further below, at least certain portions of a substrate may be masked during an implantation process in which ions of a given type are implanted into the substrate. Then when diffusion occurs, the portions of the substrate in the areas of the masked regions will have a more lightly doped concentration of the implanted ions than the unmasked substrate, increasing breakdown voltage. More particularly with respect to SCR fabrication, a common collector arrangement of the device allows a common junction formed by lightly doped P and N regions. Such a lightly doped P region may be formed by masking a portion of a P region to enable diffusion into the masked-off region, enabling a lightly doped concentration and increasing breakdown voltage. In one embodiment, ions may be implanted into unmasked areas of a region. That area will result in a lower concentration due to the masked area(s). In one diffusion, the resulting substrate may be at a concentration 1×10¹⁵ on a p type starting material having a concentration of 1×10¹⁴. In some implementations, the entire doped region may have a reduced concentration while in other embodiments the region corresponding to the masked portion(s) may have a lower concentration. That is the p region may have a varying concentration of dopants (e.g., with respect to its lateral profile). Because of the masked regions within the implanted region, the resulting concentration is thus more lightly doped than the concentration of the unmasked area, increasing breakdown voltage.

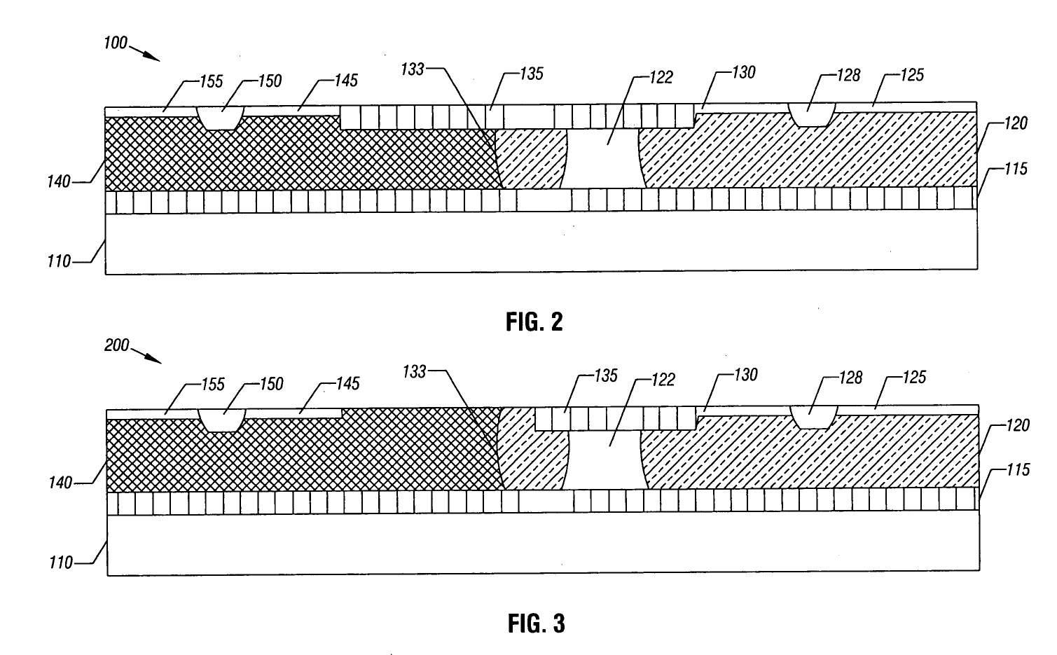

Referring now to FIG. 2, shown is a cross section of an SCR in accordance with one embodiment of the present invention. As shown in FIG. 2, SCR 100 may be formed on a substrate 110. Substrate 110 may be referred to as a handle wafer. Over substrate 110, an insulation layer 115 is formed, which in one embodiment may be a silicon dioxide (SiO₂) layer. While the scope of the present invention is not limited in this regard, layer 115 may have a thickness of between approximately 0.25 and 2.0 microns, in some embodiments. Oxide layer 115 may provide junction isolation for SCR 100.

Still referring to FIG. 2, a p-well region 120 may be formed over insulation layer 115. This p donor-type region, referred to as a p-well 120 may be formed through implantation and diffusion. During such process, a portion of p-well region 120 may be masked. More specifically, as shown in FIG. 2, a portion 122 (shown in FIG. 2 prior to diffusion) of p-well region 120 may be masked during the implantation process. Note that p-well region 120 extends from a right side of FIG. 2 to a junction 133. Via this process, a more lightly doped p-well is formed, particularly at the junction between p-well 120 and a n donor-type region referred to herein as an n-well region 140. This junction 133, which may be a substantially vertical junction between n-well 140 and p-well 120, may provide a junction between common base and collectors of the underlying transistors formed in SCR 100 by these lightly doped regions 120 and 140. In various embodiments, p-well 120 and n-well 140 may have a thickness of between approximately 1.0 micron to 3.0 microns, although the scope of the present invention is not limited in this regard.

Still referring to FIG. 2, an n+ region 125 may be formed in p-well 120. Furthermore, a p+ region 130 may similarly be formed in p-well 120. These differently doped regions may be separated by an isolation 128, which may be a shallow trench isolation (STI), in one embodiment. Another isolation region 135, which also may be an STI, is formed between p+ region 130 and an n+ doped region 145 of n-well 140. N-well 140 further includes a p+ doped region 155, which is isolated from n+ doped region 145 by an isolation 150, which also may be an STI isolation.

In SCR 100, n+ doped region 125 may correspond to an emitter of transistor Q2 of FIG. 1. Similarly, p+ doped region 130 may act as a contact to p-well 120, which corresponds to a base of transistor Q2 (and a collector of transistor Q1). The collector of transistor Q2 may correspond to n-well region 140 via a contact to n+ doped region 145. In the embodiment of FIG. 2, the emitter of transistor Q1 may be implemented via p+ region 155, while the base of transistor Q1 may be implemented as n-well 140 via a contact to n+ region 145. Further, as described above, the collector of transistor Q1 may be realized using p-well 120 via a contact to p+ doped region 130. In this way, the common base-collector diffusions of transistors Q1 and Q2 may be formed between p-well 120 and n-well 140 with a vertical junction 133 therebetween. While described with this particular implementation, it is to be understood that the scope of the present invention is not limited in this regard. Accordingly, in other embodiments, different configurations and locations of various regions may be realized, and different widths and sizes of the devices formed may be present. Furthermore, it is to be understood that the structures shown in FIG. 2 are not drawn to scale.

Other configurations are possible. For example, referring now to FIG. 3, shown is a cross section of an SCR in accordance with another embodiment of the present invention. As shown in FIG. 3, SCR 200 may be formed having the same regions and in the same relative manner as that described above with regard to FIG. 2. However, note that in the embodiment of FIG. 3, isolation region 135 is narrower and provides isolation between p+ region 130 and p-well 120 at junction 133, rather than extending all the way to n+ region 145. Using an isolation region located as shown in FIG. 3, different performance parameters may be achieved. For example, a lower breakdown voltage may exist. As an example, the breakdown voltage of the embodiment of FIG. 2 may be between 105V and 165V (depending on handle wafer voltage), while the breakdown voltage of the embodiment of FIG. 3 may extend from approximately 80V-110V. While not shown to scale in FIGS. 2 and 3, in some embodiments SCR 200 may have a narrower width than that of SCR 100. For example, n+ doped region 125 may have a width of approximately 8.4 μm in the embodiment of FIG. 2 and approximately 4.8 μm in the embodiment of FIG. 3, although the scope of the present invention is not limited in this respect, although the scope of the present invention is not limited in this respect. Note also that SCRs 100 and 200 of FIGS. 2 and 3 do not include all such layers. For example, various oxide and metal layers are not shown for ease of illustration.

Note that with regard to FIGS. 2 and 3, for ease of illustration the bypass resistors and the bond pads of FIG. 1 are not shown. However, it is to be understood that in various implementations, these components may also be located on the same substrate on which SCRs 100 and 200 are formed. In various implementations, vertical isolations, e.g., of SiO₂ may be formed on either side of SCRs 100 and 200 to effect isolation between the SCRs and other devices formed on the same substrate.

Furthermore, while not shown in the embodiments of FIGS. 2 and 3, it is to be understood that the underlying circuitry to be protected by the SCRs may further be located on the same substrate. For example, in many implementations the SCRs of FIGS. 2 and 3 may be used in an integrated SLIC device to provide high voltage protection. The high voltage protection may protect various components on the common substrate, including high voltage transistors of the SLIC, which may operate at breakdown voltages exceeding 80V, although the scope of the present invention is not limited in this regard.

Accordingly, a lateral device is formed with a vertical junction. Use of the p-wells and n-wells to establish a high voltage breakdown may enable an SCR to handle surges on a line to which the device is coupled.

Various design parameters may be considered and manipulated in forming an SCR in accordance with the present invention in order to obtain desired protection for a circuit in a minimal area. As an example, metal layers of the SCR may be formed to minimize de-biasing effects. Furthermore, such metal lines may be formed to avoid problems occurring at high currents that may pass through the metal lines. For example, when used as a surge protection device for lightning strikes, transient currents of up to 50 Amps can be received. If the current is too high, an improperly designed metal line can be harmed and rendered ineffective, e.g., via melting or blow up of a portion of the line. To that end, metal layers of an SCR in accordance with an embodiment of the present invention may be carefully designed to prevent such occurrences. For example, widths of metal lines may be maintained at least at a predetermined minimum width to provide for a desired current density level, which may vary depending on a process technology. Furthermore, the widths of different metal layers may be sized appropriately. For example, a lower metal layer, e.g., a layer 1 (L1) metal, may be thinner than metal layers stacked thereon such as a second layer metal and a third layer metal.

Contact sizes may be considered to reduce resistance. More specifically, a number of contacts may be increased to enable a desired current density. Electric field influence from metal traces may also be considered, so as not to reduce breakdown of the device. Emitter area, width and length may be considered to lower resistance and improve efficiencies. As an example, in one embodiment, emitters may have a width between approximately 4.0 μm and 10 μm. Distances between diffusions may be considered to maximize breakdown while minimizing device size. For example, well regions, such as p-wells may be spaced to increase the well resistivity. With reference back to FIG. 2, portion 122 may have a width of approximately 1.6 μm, in one embodiment. The number of bond wires used to connect one or more SCR cells to bond pads also may be considered for their current handling capability and their resistance contribution.

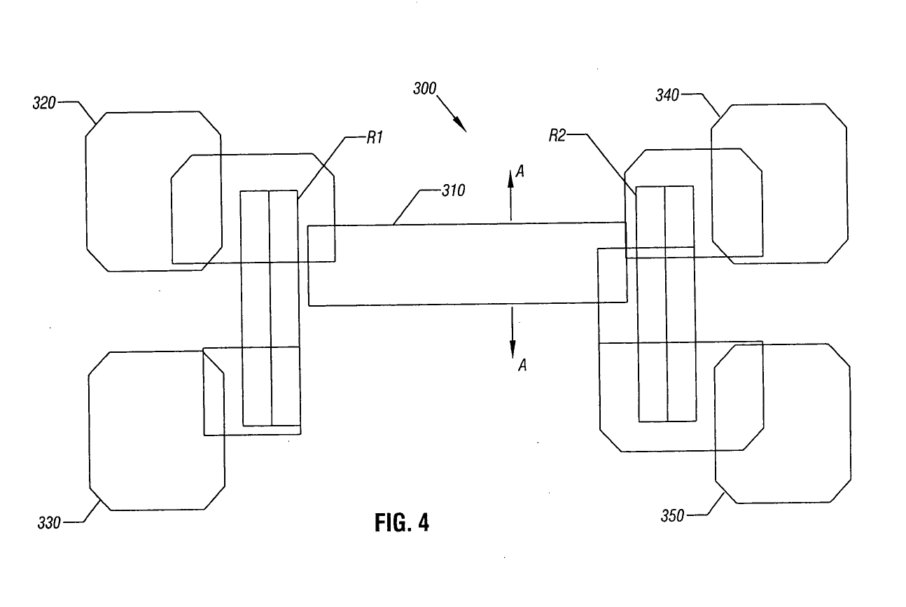

Referring now to FIG. 4, shown is a layout of a single SCR cell in accordance with an embodiment of the present invention. As shown in FIG. 4, layout 300 includes an SCR 310. Note that the cross section denoted by section A-A corresponds to the cross sections shown in FIGS. 2 and 3. SCR 310 may be coupled to bypass resistors R1 and R2 and furthermore may be coupled to bond pads 320-350. SCR 310 may be located substantially in between the pairs of bond pads to reduce metal routing to the pads to avoid IR drops across the routing lines.

While layout 300 shows only a single SCR cell, in various embodiments multiple cells may be provided on a single substrate to provide desired scaling. For example, a plurality of parallel SCRs may be located on a substrate. Furthermore, routing lines between the SCRs and bond pads may be carefully designed to reduce overall routing between any one SCR cell and a corresponding bond pad, thus reducing IR drops across these routing lines.

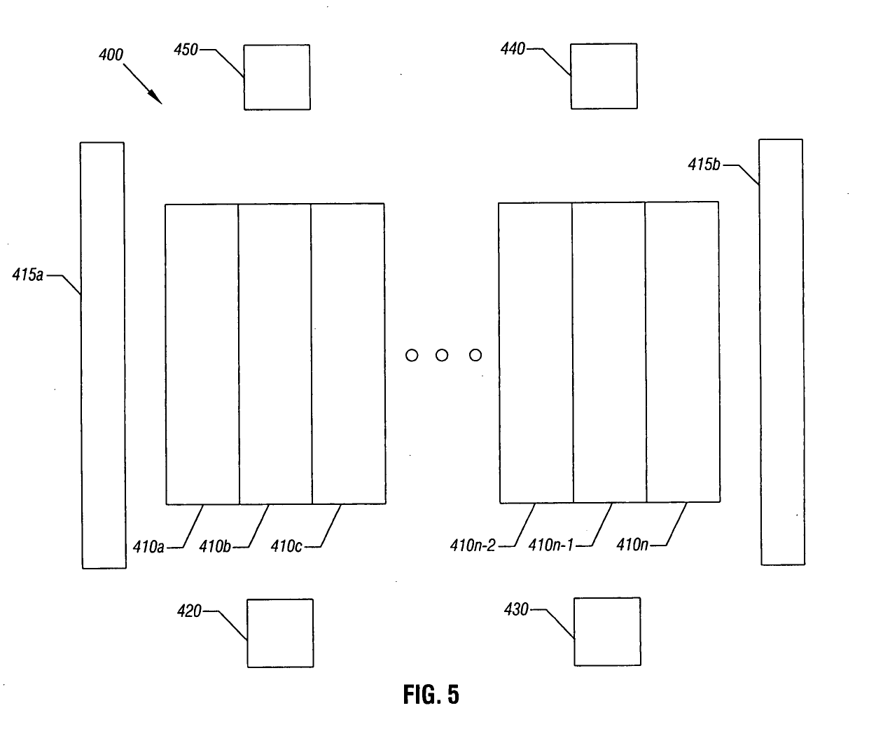

Referring now to FIG. 5, shown is a layout in accordance with another embodiment of the present invention. As shown in FIG. 5, layout 400 includes a plurality of SCR cells 410a-410n (generically SCR cell 410). As shown in FIG. 5, SCR cells 410 are situated in parallel with each other in a stepped manner such that each cell 410 is directly adjacent a mirror image of itself. Cells 410 may be enclosed within a tub or isolation, shown as isolation regions 415a and 415b, in FIG. 5. Furthermore, a plurality of bond pads 420-450 are present. As shown in FIG. 5, each bond pads may be located in the substantial middle lateral portion (i.e., symmetrically) with respect to some amount of the cells of layout 400. In this way, metal routing between a furthest SCR cell 410 and a furthest bond pad can be reduced. While not shown for ease of illustration in the embodiment of FIG. 5, it is to be understood that each SCR cell 410 may be coupled on either end to one of bond pads 420-450, via routings along the various metal layers. Then, metal wires or lines may couple the bond pads to I/O pads of the device.

As one example, a single SCR cell may have an on resistance of 4 ohm in an area of 54 μm×250 μm. Putting 30 of these stripes in parallel may thus result in an SCR with on resistances in the 0.15 ohm range in an area of 0.34 mm² (not including metal routing to pads).

While SCRs in accordance with an embodiment of the present invention can be used in many different situations, in some implementations the SCR may be used in a protection circuit. Such a protection circuit may be integrated with a circuit that it is to protect. For example, in the context of a SLIC, the SCR protection circuit and the SLIC may be integrated in a single integrated circuit (i.e., formed on a single substrate such as an SOI substrate). In this way, reduced component counts and size can be realized.

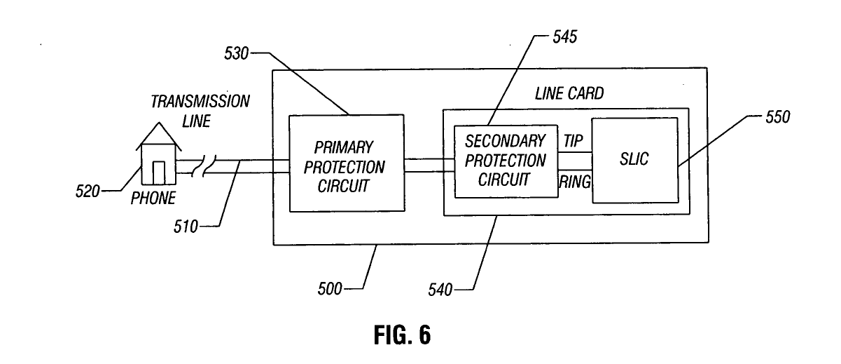

Referring now to FIG. 6, shown is a block diagram of a system in accordance with an embodiment of the present invention. As shown in FIG. 6, a central office 500 is coupled to a transmission line 510 that in turn may be coupled to a subscriber unit (e.g., telephone) 520 at a remote location, e.g., at a subscriber location. Within central office 500, a primary protection circuit 530 may be present. Primary protection circuit 530 may provide a first stage protection for surges, e.g., lightning strikes on transmission line 510. Primary protection circuit 530 may drop an incoming voltage down to a lower level, e.g., in a range of approximately 1000V. This very high voltage is then provided through primary protection circuit 530 to a line card 540 that includes a secondary protection circuit 545 and a SLIC 550. Secondary protection circuit 545 may limit the voltage seen by SLIC 550 by shunting current to ground. In various embodiments, secondary protection circuit 545 may be implemented with multiple SCRs in accordance with an embodiment of the present invention. Furthermore, while shown as separate blocks in the embodiment of FIG. 6, it is to be understood that both secondary protection circuit 545 and SLIC 550 may be adapted on a single substrate (i.e., as a single IC). Of course, an SCR in accordance with an embodiment of the present invention may be implemented for protection of other circuits such as an ADSL line driver, power over Ethernet integrated device, modems, and the like. Furthermore, SCRs in accordance with embodiments of the present invention may also be implemented in other circuitry such as motor drives, H bridges and the like.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. An apparatus comprising:
a protection circuit to provide protection from transient surges, the protection circuit including a silicon controlled rectifier formed on a substrate via a planar process; and
a circuit coupled to the protection circuit to be protected by the protection circuit, the circuit formed on the substrate.

2. The apparatus of claim 1, wherein the planar process comprises a silicon on insulator (SOI) process.

3. The apparatus of claim 1, wherein the circuit comprises a subscriber line interface circuit (SLIC).

4. The apparatus of claim 1, wherein the protection circuit comprises a first bipolar transistor and a second bipolar transistor, the bipolar transistors having a shared base-collector diffusion.

5. The apparatus of claim 4, wherein the first bipolar transistor and the second bipolar transistor have breakdown voltages greater than 120 volts.

6. The apparatus of claim 4, wherein the protection circuit further comprises a n-well region including the first bipolar transistor and a p-well region including the second bipolar transistor.

7. The apparatus of claim 6, further comprising a vertical junction between the p-well region and the n-well region.

8. The apparatus of claim 6, wherein the p-well region comprises a lightly doped region.

9. The apparatus of claim 6, wherein the first bipolar transistor includes a base terminal formed of a n+ doped portion of the n-well region and a collector terminal formed of a p+ doped portion of the p-well region.

10. The apparatus of claim 9, wherein the second bipolar transistor includes a base terminal formed of the p+ doped portion of the p-well region and a collector terminal formed of the n+ doped portion of the n-well region.

11. The apparatus of claim 10, further comprising an isolation disposed substantially between the n+ doped portion of the n-well region to the p+ doped portion of the p-well region.

12. The apparatus of claim 1, wherein the SCR comprises a plurality of SCR cells formed on the substrate substantially parallel in a stepped manner and commonly coupled to a set of bond pads, wherein an on resistance of the SCR is reduced via the plurality of SCR cells.

13. A method comprising:
forming a p-well region on a substrate via implantation of a p-type dopant along a first and second portion of the p-well region while blocking a third portion of the p-well region; and
forming a n-well region on the substrate adjacent the p-well region, wherein a vertical junction between the n-well region and the p-well region comprises a vertical junction of a lateral silicon controlled rectifier (SCR) including the p-well region and the n-well region.

14. The method of claim 13, further comprising forming an insulation layer on the substrate between a handle wafer region and the n-well region and the p-well region.

15. The method of claim 13, wherein the SCR comprises a lateral device including the vertical junction.

16. The method of claim 13, further comprising forming a circuit on the substrate, wherein the SCR comprises a protection circuit for the circuit.

17. The method of claim 16, wherein forming the circuit comprises forming a subscriber line interface circuit (SLIC) including high voltage transistors, wherein the SCR comprises high voltage transistors having a breakdown voltage greater than 120 volts.

18. The method of claim 13, further comprising forming a plurality of SCR cells on the substrate each having the p-well region and the n-well region.

19. The method of claim 18, further comprising coupling a first group of the plurality of SCR cells to a first bond pad symmetrically disposed with respect to the first group and coupling a second group of the plurality of SCR cells to a second bond pad symmetrically disposed with respect to the second group.

20. A system comprising:
a circuit formed on a substrate;
a silicon controlled rectifier (SCR) coupled to the circuit having a vertical junction between a first common collector-base terminal of a first transistor and a second transistor and a second common collector-base terminal of the second transistor and the first transistor, the SCR formed on the substrate to provide electrical protection for the circuit; and
a line card including the SCR and the circuit.

21. The system of claim 20, wherein the circuit comprises a subscriber line interface circuit (SLIC).

22. The system of claim 21, further comprising an integrated circuit including the SCR and the SLIC.

23. The system of claim 20, wherein the SCR comprises a lateral device formed above an insulation layer formed on the wafer.

24. The system of claim 20, further comprising a vertical isolation region located between the SCR and the circuit, wherein a p-well adjacent the vertical isolation region has a varying concentration of p-type dopants.
